(19) United States
(12) Patent Application Publication
(10) Pub. No.: US 2026/0303044 A1
(43) Pub. Date: Oct. 1, 2026

(54) POWER AMPLIFIER CIRCUIT AND MULTI-STAGE POWER AMPLIFIER CIRCUIT

(71) Applicant: Murata Manufacturing Co., Ltd., Nagaokakyo-shi (JP)

(72) Inventors: Yuuma NOGUCHI, Nagaokakyo-shi (JP); Kiichiro TAKENAKA, Nagaokakyo-shi (JP)

(21) Appl. No.: 19/572,189

(22) Filed: Mar. 19, 2026

(30) Foreign Application Priority Data
Mar. 25, 2025 (JP) 2025-049629

(51) Int. Cl. H03F 3/60; H03F 1/56; H03F 3/24

(52) U.S. Cl. CPC H03F 3/601; H03F 1/565; H03F 3/245; H03F 2200/451

(57) ABSTRACT

A power amplifier circuit includes a first line having one end connected to an input terminal and the other end; a second line having one end connected to the other end of the first line and the other end connected to ground, the second line being electromagnetically coupled to the first line; and a transistor having an emitter or source connected to the other end of the first line, a base or gate supplied with a bias and connected via a first capacitor to ground, and a collector or drain connected to a power supply terminal and an output terminal.

### CROSS REFERENCE TO RELATED APPLICATION

This application claims priority from Japanese Patent Application No. 2025-049629, filed on Mar. 25, 2025. The content of this application is incorporated herein by reference in its entirety.

### BACKGROUND OF THE DISCLOSURE

### 1. Field of the Disclosure

The present disclosure relates to a power amplifier circuit and a multi-stage power amplifier circuit.

### 2. Description of the Related Art

There is a common-base high-frequency amplifier circuit (see, for example, Japanese Unexamined Utility Model Registration Application Publication No. 49-132747).

### BRIEF SUMMARY OF THE DISCLOSURE

In a UHF-band high-frequency amplifier circuit described in Japanese Unexamined Utility Model Registration Application Publication No. 49-132747, an emitter of a transistor is connected via a first coil to ground. The first coil is coupled to a second coil provided between a terminal connected to a preceding-stage circuit and ground. In such a high-frequency amplifier circuit, the presence of two coils increases the circuit size.

The present disclosure has been made in view of the circumstances described above. A possible benefit of the present disclosure is to provide a power amplifier circuit and a multi-stage power amplifier circuit having a reduced circuit size.

A power amplifier circuit according to an aspect of the present disclosure includes a first line having one end connected to an input terminal and the other end; a second line having one end connected to the other end of the first line and the other end connected to ground, the second line being electromagnetically coupled to the first line; and a transistor having an emitter or source connected to the other end of the first line, a base or gate supplied with a bias and connected via a first capacitor to ground, and a collector or drain connected to a power supply terminal and an output terminal.

A multi-stage power amplifier circuit according to another aspect of the present disclosure includes a plurality of power amplifier circuits connected in series. The power amplifier circuit constituting an initial stage and connected to an input terminal is a common-base amplifier circuit or a common-gate amplifier circuit. The power amplifier circuit constituting the initial stage includes a first line having one end connected to the input terminal and the other end; a second line having one end connected to the other end of the first line and the other end connected to ground, the second line being electromagnetically coupled to the first line; and a transistor having an emitter or source connected to the other end of the first line, a base or gate supplied with a bias and connected via a first capacitor to ground, and a collector or drain connected to a power supply terminal and the power amplifier circuit subsequent to the power amplifier circuit constituting the initial stage.

The present disclosure makes it possible to provide a power amplifier circuit and a multi-stage power amplifier circuit having a reduced circuit size.

### BRIEF DESCRIPTION OF THE SEVERAL VIEWS OF THE DRAWINGS

FIG. 1 is a circuit diagram of a power amplifier circuit 101;

FIG. 2 is a diagram schematically illustrating the frequency characteristics of the gain of the power amplifier circuit 101;

FIG. 3 is a circuit diagram of a power amplifier circuit 102;

FIG. 4 is a circuit diagram of a power amplifier circuit 103;

FIG. 5 is a diagram schematically illustrating a configuration of a transmitting apparatus 301;

FIG. 6 is a circuit diagram of power amplifier circuits 101a and 101b in a multi-stage power amplifier circuit 201; and

FIG. 7 is a circuit diagram of power amplifier circuits 151a and 151b in the multi-stage power amplifier circuit 201.

### DETAILED DESCRIPTION OF THE DISCLOSURE

Hereinafter, embodiments of the present disclosure will be described in detail with reference to the accompanying drawings. Note that the same elements are denoted by the same reference numerals, and redundant descriptions thereof will be omitted as much as possible.

### First Embodiment

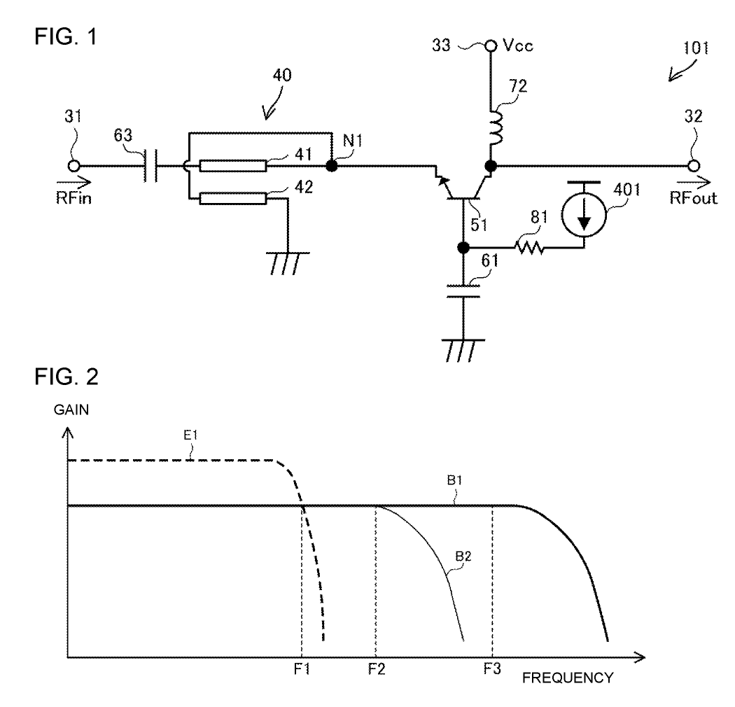

A power amplifier circuit 101 according to a first embodiment will be described. FIG. 1 is a circuit diagram of the power amplifier circuit 101. As illustrated in FIG. 1, the power amplifier circuit 101 includes a transmission line transformer 40, a transistor element 51 (transistor), a capacitor 61 (first capacitor) and a capacitor 63, an inductor 72, a resistive element 81, and a constant current source 401. The transmission line transformer 40 includes a line 41 (first line) and a line 42 (second line).

In the present embodiment, the transistor element is constituted, for example, by a bipolar transistor, such as a heterojunction bipolar transistor (HBT). The transistor element may be constituted by another type of transistor, such as a field-effect transistor (or metal-oxide-semiconductor field-effect transistor (MOSFET)). In such a case, a base, a collector, and an emitter may be read as a gate, a drain, and a source, respectively.

The power amplifier circuit 101 is a common-base power amplifier circuit. The power amplifier circuit 101 amplifies an input signal RFinsupplied to an input terminal 31, and outputs an output signal RFout from an output terminal 32.

The input signal RFin is, for example, a radio frequency (RF) signal having a frequency of 7 GHz or higher. Specifically, the input signal RFin is, for example, a signal in an 8 GHz band, a 10 GHz band, a 13 GHz band, or a 15 GHz band.

The transmission line transformer 40 matches the impedance between a circuit preceding the input terminal 31 and the transistor element 51.

The line 41 in the transmission line transformer 40 has one end connected via the capacitor 63 to the input terminal 31 and the other end connected to a node N1.

The line 42 has one end connected to the node N1 and the other end connected to ground. The line 42 is electromagnetically coupled to the line 41.

Specifically, the lines 41 and 42 are, for example, metal electrodes formed on a semiconductor chip. The line 42 is disposed along a direction in which the line 41 extends. For example, when the line 41 extends straight and a direction from the one end to the other end of the line 41 is defined as a first direction, the line 42 extends substantially parallel to the first direction. The line 42 is disposed such that a direction from the one end to the other end thereof coincides with the first direction.

The transistor element 51 is operated by a power supply voltage Vcc. The transistor element 51 amplifies the input signal RFin supplied from the input terminal 31 via the capacitor 63, the line 41, and the node N1 and outputs the output signal RFout as an amplified signal to the output terminal 32.

Specifically, the transistor element 51 is formed on the semiconductor chip. In the present embodiment, the semiconductor chip includes, for example, gallium and arsenic.

The transistor element 51 has an emitter connected to the node N1, a base supplied with a bias and connected via the capacitor 61 to ground, and a collector connected to a voltage supply terminal 33 and the output terminal 32.

The constant current source 401 supplies a constant current via the resistive element 81 to the base of the transistor element 51. A bias is thus supplied to the base of the transistor element 51.

The voltage supply terminal 33 (power supply terminal) supplies the power supply voltage Vcc for operating the transistor element 51. The inductor 72 has one end connected to the voltage supply terminal 33 and the other end connected to the collector of the transistor element 51.

When the transistor element 51 is in an ON state, a direct current flows from the voltage supply terminal 33 to ground via the inductor 72, the collector of the transistor element 51, the emitter of the transistor element 51, the node N1, and the line 42. That is, the emitter of the transistor element 51 serves as a ground for a direct-current component of the current.

The line 42 has a high impedance to the input signal RFin having a high frequency. Consequently, the input signal RFin flows very little from the node N1 to the line 42, and flows to ground via the capacitor 63, the line 41, the node N1, the emitter of the transistor element 51, the base of the transistor element 51, and the capacitor 61. That is, the base of the transistor element 51 serves as a ground for an alternate-current component of the current.

### Effects

FIG. 2 is a diagram schematically illustrating the frequency characteristics of the gain of the power amplifier circuit 101. Note that the vertical axis and the horizontal axis represent gain and frequency, respectively.

As illustrated in FIG. 2, a curve B1 represents how the gain of the common-base power amplifier circuit 101 changes with frequency. A curve E1 represents how the gain of a common-emitter power amplifier circuit changes with frequency. Details of the common-emitter power amplifier circuit will be described below.

In a frequency region lower than the frequency F1, the curve B1 exhibits a lower gain than the curve E1, whereas in a frequency region higher than the frequency F1, the curve B1 exhibits a higher gain than the curve E1.

That is, the power amplifier circuit 101 can achieve a higher gain in a frequency region higher than the frequency F1.

In the present embodiment, since the semiconductor chip on which the transistor element 51 is formed includes gallium and arsenic, the frequency F1 is about 7 GHz.

With a configuration in which the transmission line transformer 40, instead of a transformer including a coil (winding), is provided in a stage preceding the transistor element 51, the circuit size can be reduced.

With a configuration in which the transmission line transformer 40 having wide frequency characteristics is provided, instead of a transformer including a coil, a high gain can be achieved over a wide frequency band.

With a configuration in which the other end of the line 41 and the emitter of the transistor element 51 are connected to ground via the line 42, the resistance from the emitter of the transistor element 51 to ground can be reduced. This can suppress an increase in the potential of the emitter of the transistor element 51 and increase a potential difference between the emitter and the collector of the transistor element 51, so that the output signal RFout with a large amplitude can be outputted. Additionally, the heat generation based on a direct current flowing from the emitter of the transistor element 51 to ground can be reduced.

Moreover, since the distance from the emitter of the transistor element 51 to ground can be shortened, the heat generated in the transistor element 51 can be efficiently conducted to ground and dissipated, so that an increase in the temperature of the transistor element 51 can be suppressed.

Also, with a configuration in which the one end of the line 42 is connected to the other end of the line 41, the input impedance of the transistor element 51 can be reduced compared to the case where the one end of the line 42 is connected to the one end of the line 41.

### Second Embodiment

A power amplifier circuit 102 according to a second embodiment will now be described. In the second and subsequent embodiments, descriptions of matters common to the first embodiment will be omitted, and only differences will be described. In particular, similar effects achieved by similar configurations will not be repeatedly mentioned for each embodiment.

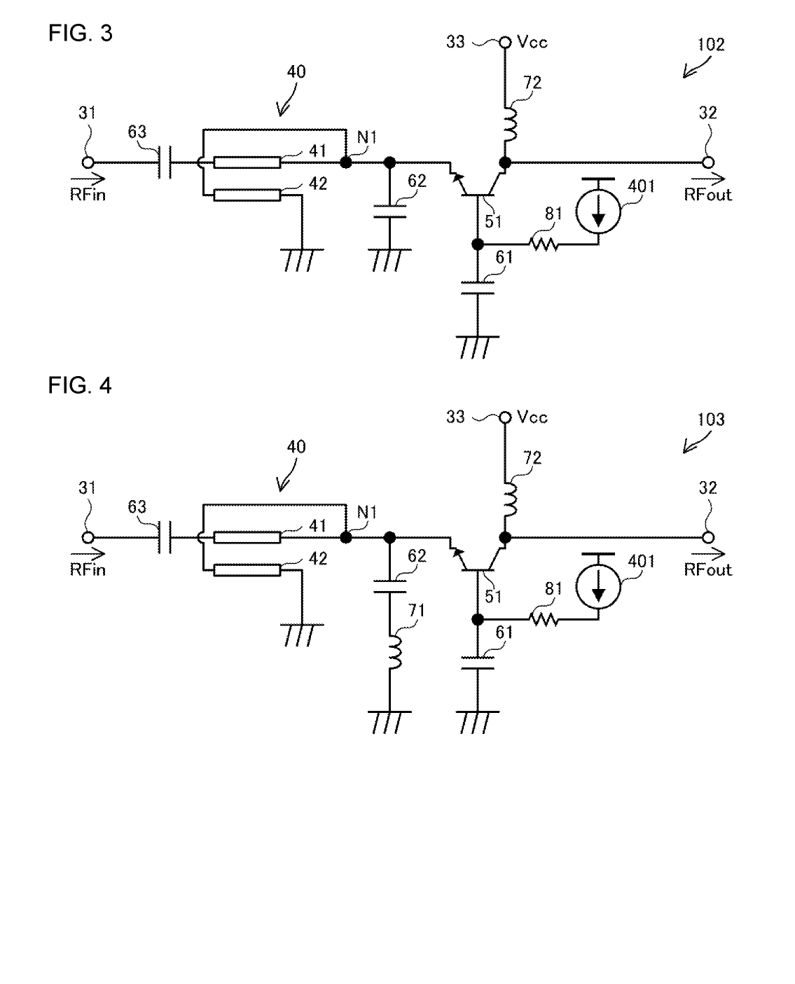

FIG. 3 is a circuit diagram of the power amplifier circuit 102. As illustrated in FIG. 3, the power amplifier circuit 102 according to the second embodiment differs from the power amplifier circuit 101 according to the first embodiment in that the power amplifier circuit 102 further includes a capacitor 62 (second capacitor).

The capacitor 62 has one end connected to the node N1 and the other end connected to ground.

### Effects

When a radio frequency signal has a high frequency, the radio frequency signal easily propagates through space. In the power amplifier circuit 101, a high gain in a high-frequency region may cause oscillation in the high-frequency region.

In contrast, in the power amplifier circuit 102, the capacitor 62 can serve as a low pass filter. Therefore, as indicated by the curve B2 in FIG. 2, the gain in a frequency region that is not intended to be amplified (for example, a frequency region higher than or equal to the frequency F2) can be reduced.

The possibility that oscillation will occur in the frequency region higher than or equal to the frequency F2 can thus be reduced, so that the power amplifier circuit 102 can operate properly.

### Third Embodiment

A power amplifier circuit 103 according to a third embodiment will now be described. FIG. 4 is a circuit diagram of the power amplifier circuit 103. As illustrated in FIG. 4, the power amplifier circuit 103 according to the third embodiment differs from the power amplifier circuit 102 according to the second embodiment in that the power amplifier circuit 103 further includes an inductor 71.

The inductor 71 of the power amplifier circuit 103 is provided between the node N1 and ground and is connected in series with the capacitor 62.

In the present embodiment, the inductor 71 has one end connected via the capacitor 62 to the node N1 and the other end connected to ground.

The inductor 71 may be configured to have one end connected to the node N1 and the other end connected via the capacitor 62 to ground.

### Effects

The configuration in which the capacitor 62 and the inductor 71 are connected in series enables the capacitor 62 and the inductor 71 to serve as a resonant circuit. Therefore, appropriately setting the resonant frequency of the resonant circuit can reduce the gain in a frequency band in which oscillation occurs. The possibility that oscillation will occur can thus be reduced, so that the power amplifier circuit 103 can operate properly.

### Fourth Embodiment

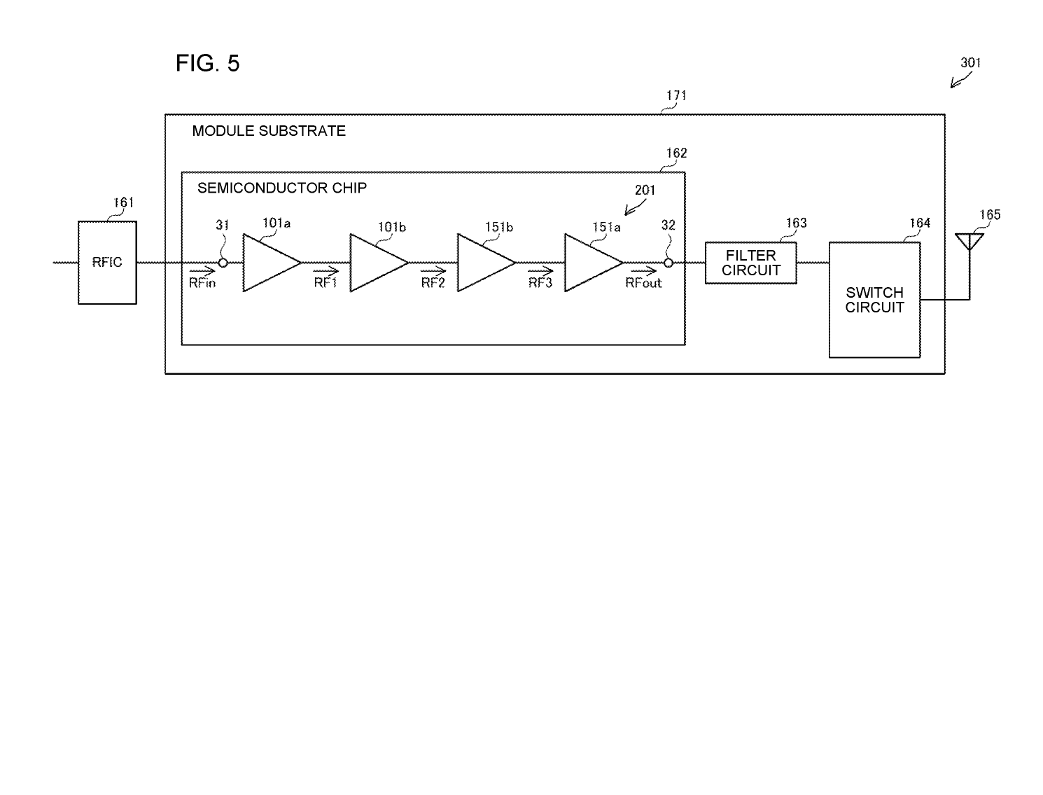

A transmitting apparatus 301 according to a fourth embodiment will now be described. FIG. 5 is a diagram illustrating a configuration of the transmitting apparatus 301.

As illustrated in FIG. 5, the power amplifier circuit 101 included in the transmitting apparatus 301 according to the fourth embodiment differs from the power amplifier circuit 101 according to the first embodiment in that another power amplifier circuit is connected in series with the power amplifier circuit 101.

The transmitting apparatus 301 includes a radio frequency integrated circuit (RFIC) 161, a module substrate 171, and an antenna 165. The module substrate 171 includes a semiconductor chip 162, a filter circuit 163, and a switch circuit 164.

A multi-stage power amplifier circuit 201 is formed on the semiconductor chip 162. The multi-stage power amplifier circuit 201 includes one or more common-base power amplifier circuits, and one or more common-emitter power amplifier circuits. The one or more common-emitter power amplifier circuits are provided in a stage subsequent to the one or more common-base power amplifier circuits. These power amplifier circuits are connected in series.

In the present embodiment, the multi-stage power amplifier circuit 201 includes power amplifier circuits 101a, 101b, 151a, and 151b connected in series. The power amplifier circuits 101a, 101b, 151b, and 151a are connected in series in this order from the input terminal 31 toward the output terminal 32.

Hereinafter, the power amplifier circuits 151a and 151b may each be referred to as a power amplifier circuit 151. The power amplifier circuit 151 is a common-emitter power amplifier circuit. Details of the power amplifier circuit 151 will be described below.

The power amplifier circuits 101a and 101b are examples of the power amplifier circuit 101. Note that at least one of the power amplifier circuits 101a and 101b may be the power amplifier circuit 102 or 103.

The RFIC 161 supplies the input signal RFin to the multi-stage power amplifier circuit 201. The multi-stage power amplifier circuit 201 amplifies the input signal RFin supplied from the RFIC 161 via the input terminal 31 and outputs the output signal RFout.

The filter circuit 163 is, for example, a low pass filter or a band pass filter. A plurality of filter circuits 163 may be provided.

The switch circuit 164 switches a connection destination of the antenna 165 to one of the plurality of filter circuits 163. A plurality of antennas 165 may be provided. In this case, the switch circuit 164 switches electrical connections between the plurality of antennas 165 and the plurality of filter circuits 163.

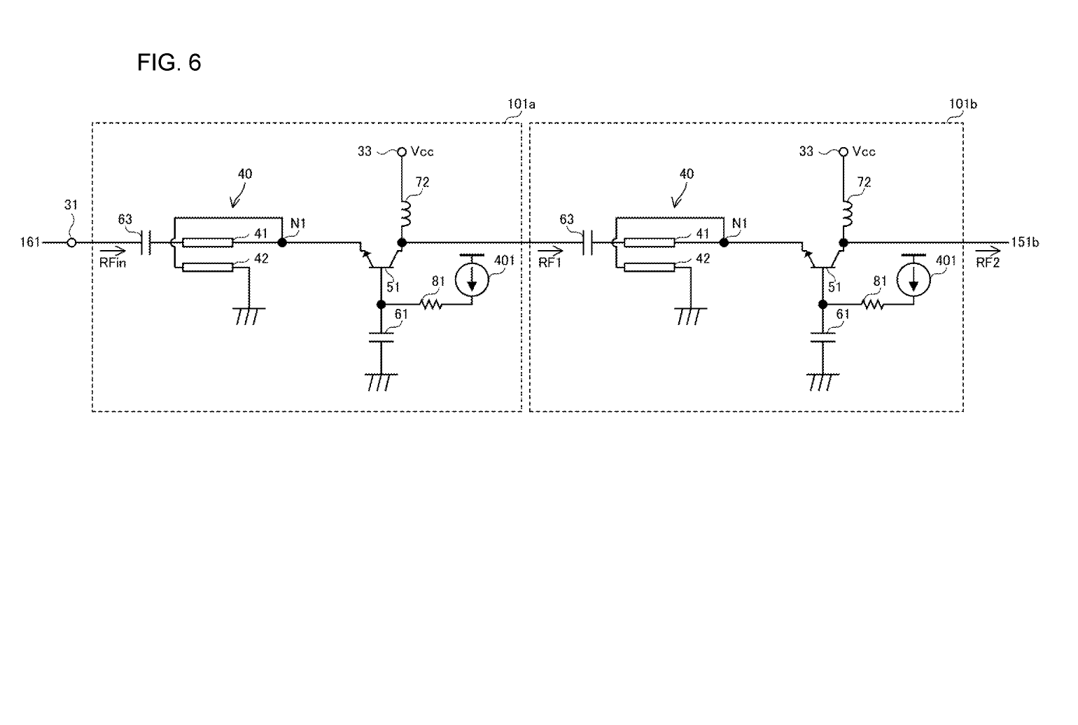

FIG. 6 is a circuit diagram of the power amplifier circuits 101a and 101b in the multi-stage power amplifier circuit 201. As illustrated in FIGS. 5 and 6, in the multi-stage power amplifier circuit 201, the power amplifier circuit 101a constituting an initial stage and the power amplifier circuit 101b subsequent to the power amplifier circuit 101a are common-base power amplifier circuits.

Specifically, the one end of the line 41 in the power amplifier circuit 101a constituting the initial stage is connected via the capacitor 63 and the input terminal 31 to the RFIC 161.

The transistor element 51 in the power amplifier circuit 101a amplifies the input signal RFin supplied from the RFIC 161 via the input terminal 31 and outputs an amplified signal RF1 to the power amplifier circuit 101b.

The one end of the line 41 in the power amplifier circuit 101b subsequent to the power amplifier circuit 101a is connected via the capacitor 63 to the collector of the transistor element 51 in the power amplifier circuit 101a.

The collector of the transistor element 51 in the power amplifier circuit 101b is connected to the power amplifier circuit 151b.

The transistor element 51 in the power amplifier circuit 101b amplifies the amplified signal RF1 supplied from the power amplifier circuit 101a and outputs an amplified signal RF2 to the power amplifier circuit 151b.

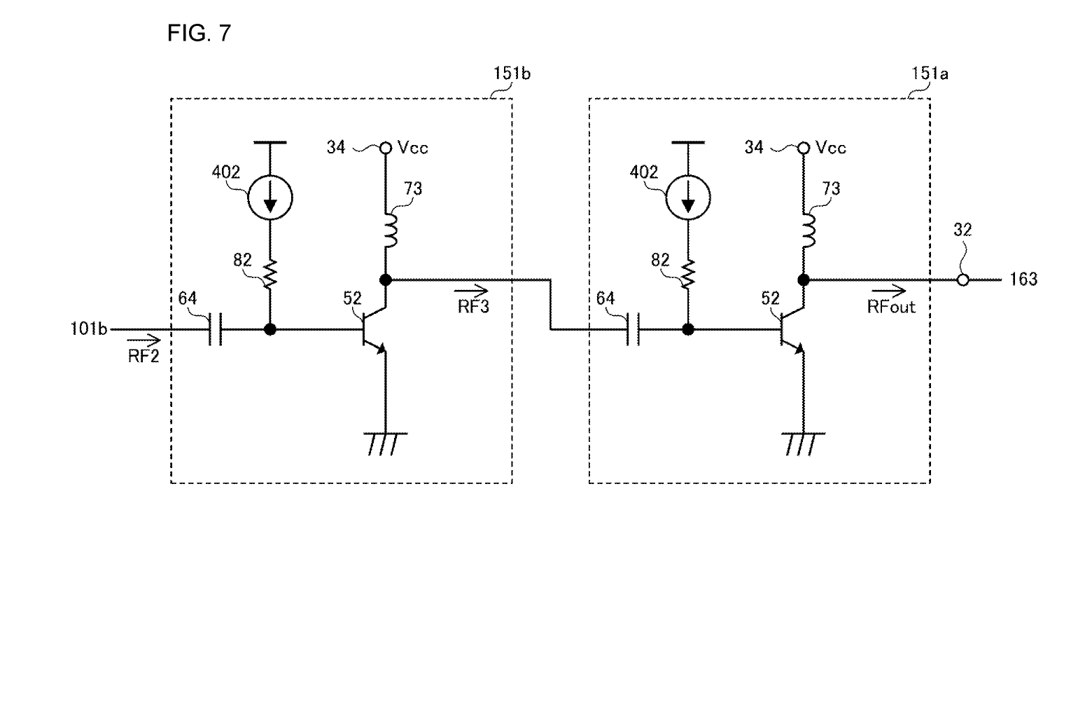

FIG. 7 is a circuit diagram of the power amplifier circuits 151a and 151b in the multi-stage power amplifier circuit 201. As illustrated in FIGS. 5 to 7, in the present embodiment, the power amplifier circuit 151a constituting a final stage and the power amplifier circuit 151b preceding the power amplifier circuit 151a are common-emitter power amplifier circuits.

The power amplifier circuit 151 includes a transistor element 52, a capacitor 64, an inductor 73, a resistive element 82, and a constant current source 402.

The transistor element 52 in the power amplifier circuit 151b amplifies the amplified signal RF2 supplied from the power amplifier circuit 101b and outputs an amplified signal RF3 to the power amplifier circuit 151a.

The transistor element 52 in the power amplifier circuit 151b has a collector connected via the inductor 73 to the voltage supply terminal 34, a base supplied with a bias and connected via the capacitor 64 to the collector of the transistor element 51 in the power amplifier circuit 101b, and an emitter connected to ground.

The constant current source 402 supplies a constant current via the resistive element 82 to the base of the transistor element 52. A bias is thus supplied to the base of the transistor element 52.

The voltage supply terminal 34 supplies the power supply voltage Vcc for operating the transistor element 52.

The transistor element 52 in the power amplifier circuit 151a amplifies the amplified signal RF3 supplied from the power amplifier circuit 151b and outputs the output signal RFout to the output terminal 32.

In the transistor element 52 in the power amplifier circuit 151a, the collector is connected via the inductor 73 to the voltage supply terminal 34 and is connected via the output terminal 32 to the filter circuit 163; the base is supplied with a bias from the constant current source 402 via the resistive element 82 and is connected via the capacitor 64 to the collector of the transistor element 52 in the power amplifier circuit 151b; and the emitter is connected to ground.

In the present embodiment, a configuration in which the multi-stage power amplifier circuit 201 includes four power amplifier circuits has been described, but the present disclosure is not limited to this. The multi-stage power amplifier circuit 201 may be configured to include two, three, five, or more power amplifier circuits.

In the present embodiment, a configuration in which the power amplifier circuit 101b subsequent to the power amplifier circuit 101a constituting the initial stage is a common-base power amplifier circuit has been described, but the present disclosure is not limited to this. The power amplifier circuit 101b subsequent to the power amplifier circuit 101a constituting the initial stage may be configured as a common-emitter power amplifier circuit.

In the present embodiment, a configuration in which the power amplifier circuit 151b preceding the power amplifier circuit 151a constituting the final stage is a common-emitter power amplifier circuit has been described, but the present disclosure is not limited to this. The power amplifier circuit 151b preceding the power amplifier circuit 151a constituting the final stage may be configured as a common-base power amplifier circuit.

In the present embodiment, a configuration in which the power amplifier circuits 101a and 101b are common-base power amplifier circuits has been described, but the present disclosure is not limited to this. At least one of the power amplifier circuits 101a and 101b may be configured as a common-gate power amplifier circuit.

In the present embodiment, a configuration in which the power amplifier circuits 151a and 151b are common-emitter power amplifier circuits has been described, but the present disclosure is not limited to this. At least one of the power amplifier circuits 151a and 151b may be configured as a common-source power amplifier circuit.

Exemplary embodiments of the present disclosure have been described. The power amplifier circuits 101, 102, and 103 each include the lines 41 and 42 and the transistor element 51. The line 41 has one end connected to the input terminal 31 and the other end. The line 42 has one end connected to the other end of the line 41 and the other end connected to ground. The line 42 is electromagnetically coupled to the line 41. The transistor element 51 has an emitter or source connected to the other end of the line 41, a base or gate supplied with a bias and connected via the capacitor 61 to ground, and a collector or drain connected to the voltage supply terminal 33 and the output terminal 32.

Thus, with a configuration in which the transmission line transformer 40, instead of a transformer including a coil, is provided in a stage preceding the transistor element 51, the circuit size can be reduced. Accordingly, a power amplifier circuit having a reduced circuit size can be provided. With a configuration in which the power amplifier circuit 101 is a common-base amplifier circuit or a common-gate amplifier circuit, a high gain can be achieved in a high-frequency region. Also, with a configuration in which the transmission line transformer 40 having wide frequency characteristics is provided, instead of a transformer including a coil, a high gain can be achieved over a wide frequency band.

In the power amplifier circuit 102, the capacitor 62 is provided between the other end of the line 41 and ground.

When a radio frequency signal has a high frequency, the radio frequency signal easily propagates through space. In the power amplifier circuit 101, a high gain in a high-frequency region may cause oscillation in the high-frequency region. In contrast, with a configuration in which the capacitor 62 is provided between the other end of the line 41 and ground, the capacitor 62 can serve as a low pass filter, so that a gain in a high-frequency region that is not intended to be amplified can be reduced. The possibility that oscillation will occur in the high-frequency region can thus be reduced, so that the power amplifier circuit 102 can operate properly.

In the power amplifier circuit 103, the inductor 71 is provided between the other end of the line 41 and ground and is connected in series with the capacitor 62.

The configuration in which the capacitor 62 and the inductor 71 are connected in series enables the capacitor 62 and the inductor 71 to serve as a resonant circuit. Therefore, appropriately setting the resonant frequency of the resonant circuit can reduce the gain in a frequency band in which oscillation occurs. The possibility that oscillation will occur can thus be reduced, so that the power amplifier circuit 103 can operate properly.

The multi-stage power amplifier circuit 201 includes a plurality of power amplifier circuits connected in series. The power amplifier circuit 101a constituting an initial stage and connected to the input terminal 31 is a common-base amplifier circuit or a common-gate amplifier circuit. The power amplifier circuit 101a constituting the initial stage includes the lines 41 and 42 and the transistor element 51. The line 41 has one end connected to the input terminal 31 and the other end. The line 42 has one end connected to the other end of the line 41 and the other end connected to ground. The line 42 is electromagnetically coupled to the line 41. The transistor element 51 has an emitter or source connected to the other end of the line 41, a base or gate supplied with a bias and connected via the capacitor 61 to ground, and a collector or drain connected to the voltage supply terminal 33 and the power amplifier circuit subsequent to the power amplifier circuit 101a.

Thus, with a configuration in which the transmission line transformer 40, instead of a transformer including a coil, is provided in a stage preceding the transistor element 51, the circuit size can be reduced. Accordingly, a multi-stage power amplifier circuit having a reduced circuit size can be provided. With a configuration in which the power amplifier circuit 101a is a common-base amplifier circuit or a common-gate amplifier circuit, a high gain can be achieved in a high-frequency region. Also, with a configuration in which the transmission line transformer 40 having wide frequency characteristics is provided, instead of a transformer including a coil, a high gain can be achieved over a wide frequency band. For example, if all power amplifier circuits included in the multi-stage power amplifier circuit are common-emitter amplifier circuits or common-source amplifier circuits, the gain sharply decreases in a high-frequency region and the frequency characteristics of the gain deteriorate. In contrast, with a configuration in which the power amplifier circuit 101a constituting the initial stage is a common-base amplifier circuit or a common-gate amplifier circuit, it is possible to boost the gain in a high-frequency region where a common-emitter amplifier circuit or a common-source amplifier circuit cannot achieve a sufficient gain. This can suppress a sharp decrease in gain in a high-frequency region and improve the frequency characteristics of the gain.

In the multi-stage power amplifier circuit 201, the power amplifier circuit 151a constituting a final stage and connected to the output terminal 32 is a common-emitter amplifier circuit or a common-source amplifier circuit.

Thus, with a configuration in which the power amplifier circuit 151a constituting the final stage, through which a large current flows, is a common-emitter amplifier circuit or common-source amplifier circuit having improved heat dissipation characteristics, the heat generated in the power amplifier circuit 151a can be efficiently dissipated. An increase in the temperature of the power amplifier circuit 151a can thus be reduced. This enables the multi-stage power amplifier circuit 201 to operate in a thermally stable manner.

The multi-stage power amplifier circuit 201 includes three or more power amplifier circuits. The power amplifier circuit 101b subsequent to the power amplifier circuit 101a is a common-base amplifier circuit or a common-gate amplifier circuit.

Thus, with a configuration in which a power amplifier circuit constituting an initial stage and a power amplifier circuit subsequent thereto each are a common-base amplifier circuit or a common-gate amplifier circuit, it is possible to effectively boost the gain in a high-frequency region where a common-emitter amplifier circuit or a common-source amplifier circuit cannot achieve a sufficient gain. This can suppress a sharp decrease in gain in a high-frequency region and further improve the frequency characteristics of the gain.

The multi-stage power amplifier circuit 201 includes three or more power amplifier circuits. The power amplifier circuit 151b preceding the power amplifier circuit 151a constituting the final stage is a common-emitter amplifier circuit or a common-source amplifier circuit.

Thus, with a configuration in which a power amplifier circuit constituting a final stage, through which a large current flows, and a power amplifier circuit preceding the power amplifier circuit constituting the final stage each are a common-emitter amplifier circuit or common-source amplifier circuit having improved heat dissipation characteristics, the heat generated in the power amplifier circuit 151a can be efficiently dissipated. An increase in the temperature of the power amplifier circuit 151a can thus be reduced. This enables the multi-stage power amplifier circuit 201 to operate in a more thermally stable manner.

The embodiments described above are intended to facilitate understanding of the present disclosure and are not intended to limit the interpretation of the present disclosure. The present disclosure can be modified or improved without departing from the spirit thereof, and the present disclosure includes equivalents thereof. That is, embodiments to which design changes are appropriately made by those skilled in the art are also included in the scope of the present disclosure, as long as they have the features of the present disclosure. For example, the elements included in each embodiment and their arrangements, materials, conditions, shapes, and sizes are not limited to the illustrated ones and may be changed appropriately. The embodiments are merely examples. Some of the configurations presented in different embodiments may be replaced or combined, and may also be included in the scope of the present disclosure, as long as they include the features of the present disclosure.

What is claimed is:

1. A power amplifier circuit comprising:
a first line having a first end connected to an input terminal;
a second line having a first end connected to a second end of the first line, and a second end connected to ground, the second line being electromagnetically coupled to the first line; and
a transistor having an emitter or source connected to the second end of the first line, a base or gate supplied with a bias and connected via a first capacitor to ground, and a collector or drain connected to a power supply terminal and to an output terminal.

2. The power amplifier circuit according to claim 1, wherein the power amplifier circuit further comprises a second capacitor between the second end of the first line and ground.

3. The power amplifier circuit according to claim 2, wherein the power amplifier circuit further comprises an inductor between the second end of the first line and ground, and connected in series with the second capacitor.

4. A multi-stage power amplifier circuit comprising:
a plurality of power amplifier circuits connected in series to form a plurality of stages,
wherein the power amplifier circuit of an initial stage is connected to an input terminal and is a common-base amplifier circuit or a common-gate amplifier circuit; and
wherein the power amplifier circuit of the initial stage comprises:
a first line having a first end connected to the input terminal,
a second line having a first end connected to a second end of the first line, and a second end connected to ground, the second line being electromagnetically coupled to the first line, and
a transistor having an emitter or source connected to the second end of the first line, a base or gate supplied with a bias and connected via a first capacitor to ground, and a collector or drain connected to a power supply terminal and to the power amplifier circuit of a stage subsequent to the initial stage.

5. The multi-stage power amplifier circuit according to claim 4, wherein the power amplifier circuit of a final stage is connected to an output terminal and is a common-emitter amplifier circuit or a common-source amplifier circuit.

6. The multi-stage power amplifier circuit according to claim 5,
wherein the multi-stage power amplifier circuit comprises three or more power amplifier circuits, and
wherein the power amplifier circuit of the stage subsequent to the initial stage is a common-base amplifier circuit or a common-gate amplifier circuit.

7. The multi-stage power amplifier circuit according to claim 5,
wherein the multi-stage power amplifier circuit comprises three or more power amplifier circuits, and
wherein the power amplifier circuit of a stage preceding the final stage is a common-emitter amplifier circuit or a common-source amplifier circuit.
